(19) United States
(12) Patent Application Publication
(10) Pub. No.: US 2023/0394999 A1
(43) Pub. Date: Dec. 7, 2023

(54) UPDATEABLE AND ILLUMINATED DISPLAY SIGN

(71) Applicant: The Technologist Store LLC, Hauppauge, NY (US)

(72) Inventor: Scott Brooker, Commack, OH (US)

(21) Appl. No.: 18/205,304

(22) Filed: Jun. 2, 2023

Related U.S. Application Data
(60) Provisional application No. 63/365,738, filed on Jun. 2, 2022.

(51) Int. Cl. G09F 9/33; G02F 1/167; G02F 1/16753; G02F 1/133; H05K 5/02; H05K 5/00

(52) U.S. Cl. CPC G09F 9/33; G02F 1/167; G02F 1/16753; G02F 1/13324; H05K 5/0204; H05K 5/0247; H05K 5/0021

(57) ABSTRACT

A digital sign including both a light-emitting diode display and a display screen contained within a housing unit. A control module is provided to control the light-emitting diode display and the display screen; and a power source is provided to provide power to the light-emitting diode display, the display screen and the control module. A cover plate is securable to the housing unit to contain the light-emitting diode display, the display screen, the control module, and the power source. The light-emitting diode display and the display screen are visible from outside of the housing unit and the control module and the power source are not visible from outside the housing unit.

### CROSS REFERENCE TO RELATED APPLICATIONS

This application claims the priority benefit of U.S. Provisional Patent Application No. 63/365,738, filed Jun. 2, 2022, the contents of which are hereby incorporated herein by reference in its entirety.

### BACKGROUND

Address signs for use on the exterior of houses, apartments, offices, and other buildings are well known. Presently, a person who desires to display their physical street address on a house must use a static sign with static numbers to represent the address to the persons who are able to visually see the sign that is meant to indicate a location. This sign must be in a location that is visible to the persons who are visually looking for an address to enter or drop a package off. To update the style, color, font, or graphic displayed the user must replace the existing sign with another static sign or numbers. There are currently lit address signs using light-emitting diode lights (LED's), but they are not customizable in real time.

Most of the time the sign is just numbers without the actual street name on the sign. Further, most current signs do not allow for both custom fonts, custom background images, or custom background colors that allow the user to express themselves on a display that is public facing their front door.

The reason address identifier signs do not use an updateable screen is because, with current LCD screens or even OLED screens, they need power to continuously display the message. This drains a battery-operated device much faster, or it would require a hardwired power connection for the device to continue to work.

Therefore, there is a need in the art for a sign that overcomes the static nature of house address signs and allows for custom fonts, graphics, and text to be displayed for a unique updateable visual experience at each house or building that garners more attention than nothing at all.

### BRIEF DESCRIPTION OF THE DRAWINGS

The accompanying drawings, which are incorporated into and form a part of the specification, schematically illustrate one or more example implementations of the disclosed inventive subject matter and, together with the general description given above and detailed description given below, serve to explain the principles of the disclosed subject matter, and wherein:

FIG. 1 is a front perspective view of one embodiment of the display device of the present disclosure secured to a house;

FIG. 2 is a front perspective view of the display device of FIG. 1 not secured to the house;

FIG. 3 is an exploded view of the display device of FIG. 2;

FIG. 4 is a front view of one embodiment of the display device of the present disclosure showing the internal components housed therein;

FIG. 5 is front view of one embodiment of the display device; and

FIG. 6 is an upward looking perspective view of one embodiment of the display device.

### DETAILED DESCRIPTION

Various non-limiting embodiments of the present disclosure will now be described to provide an overall understanding of the principles of the structure, function, and use of the systems and processes disclosed herein. One or more examples of these non-limiting embodiments are illustrated in the accompanying drawings. Those of ordinary skill in the art will understand that systems and methods specifically described herein and illustrated in the accompanying drawings are non-limiting embodiments. The features illustrated or described in connection with one non-limiting embodiment may be combined with the features of other non-limiting embodiments. Such modifications and variations are intended to be included within the scope of the present disclosure.

Reference throughout the specification to “various embodiments,” “some embodiments,” “one embodiment,” “some example embodiments,” “one example embodiment,” or “an embodiment” means that a particular feature, structure, or characteristic described in connection with any embodiment is included in at least one embodiment. Thus, appearances of the phrases “in various embodiments,” “in some embodiments,” “in one embodiment,” “some example embodiments,” “one example embodiment,” or “in an embodiment” in places throughout the specification are not necessarily all referring to the same embodiment. Furthermore, the features, structures or characteristics may be combined in any suitable manner in one or more embodiments.

As stated above, the reason address identifier signs do not use an updateable screen is because with current LCD screens or even OLED screens they need power to continue to display the message. In one or more embodiments, the device of the present disclosure utilizes an e-paper (e-ink) screen with the ability to hold an image on it indefinitely without power being applied to the device at all, meaning set it once and it will display for an extended period of time unpowered. In one or more embodiments, the device of the present disclosure will also have different functionalities such that it can be set to update once a day, say at midnight, for up to 6 months without recharging the battery at all. In one or more embodiments, the device of the present disclosure will utilize solar panels and/or an exterior charging port which provides for multiple ways to recharge the internal battery.

In one or more embodiments, the device of the present disclosure will display a scrolling text message inside an LED matrix that allows for communication in the form of a text message that has either the address itself or even a custom message for the visitor. In one or more embodiments, the device can also flash to gain the attention of a passerby or someone who needs to quickly identify a location to render assistance and could be run on a 3-hour timer to deactivate and return to normal state of operation, i.e., the house or building address is displayed again.

For example, a homeowner sees the two people who are trying to solicit a response from the homeowner by ringing the doorbell and asking questions, all unwanted actions. The homeowner could utilize the device of the present disclosure to scroll a message saying, “NO soliciting you two, now please leave the property!” and the message would then scroll informing whomever was at the front door that they needed to leave.

In yet another example, a homeowner could utilize a customized drawing as a background for the address displayed on the device of the present disclosure that displays the address number in contrasting color with or without the street name, then provide credit to the artist of the drawing.

In yet another example, in an emergency, sometimes when searching for the address, valuable time is wasted looking for the location by the first responder. However, if a display sign could draw more attention to the location with flashing lights and/or with a scrolling text message, “Help Needed Inside,” there is the possibility it could help save time in that emergency response situation.

In one or more embodiments, the display device of the present disclosure overcomes the static nature of house address signs and allows for custom fonts, graphics, and text to be displayed for a unique updateable visual experience at each house or building that garners more attention than nothing at all. However, in one or more embodiments, after each event the display device of the present disclosure defaults to the main address again after a set-amount of time after a specific graphic or message is shown on the display device.

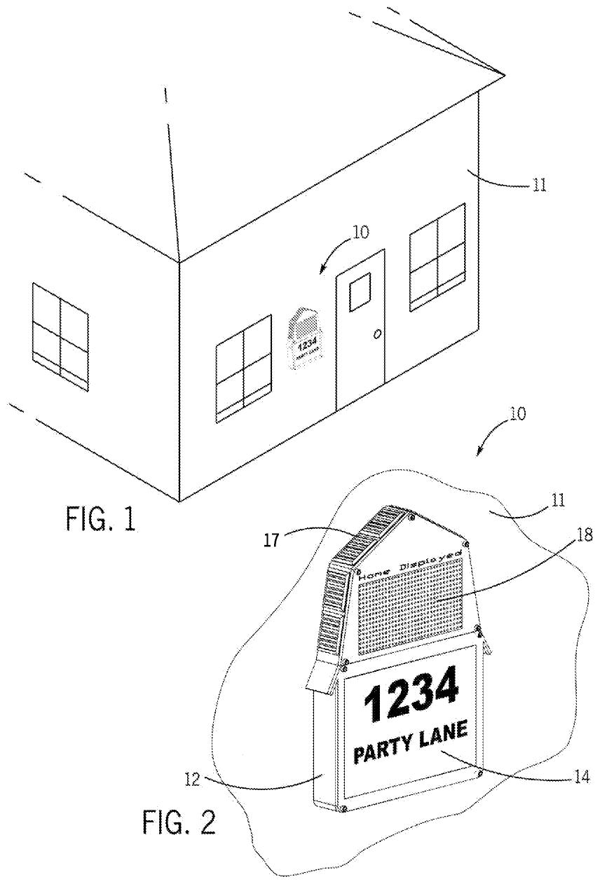

FIG. 1 shows device 10 mounted on a house 11 according to an embodiment of the present disclosure. FIG. 2 shows an embodiment of device 10 not secured to the house 11. Device 10 comprises a housing 12 with a roofing structure 16. Device 10 further comprises a light-emitting diode (LED) display 18 and a display screen 14. In one or more embodiments, the display screen 14 may be an electronic paper (e-paper) or electronic ink (e-ink) screen. In one or more embodiments, the LED display 18 displays scrolling or static images including text in RGB (red, green, and blue) colors.

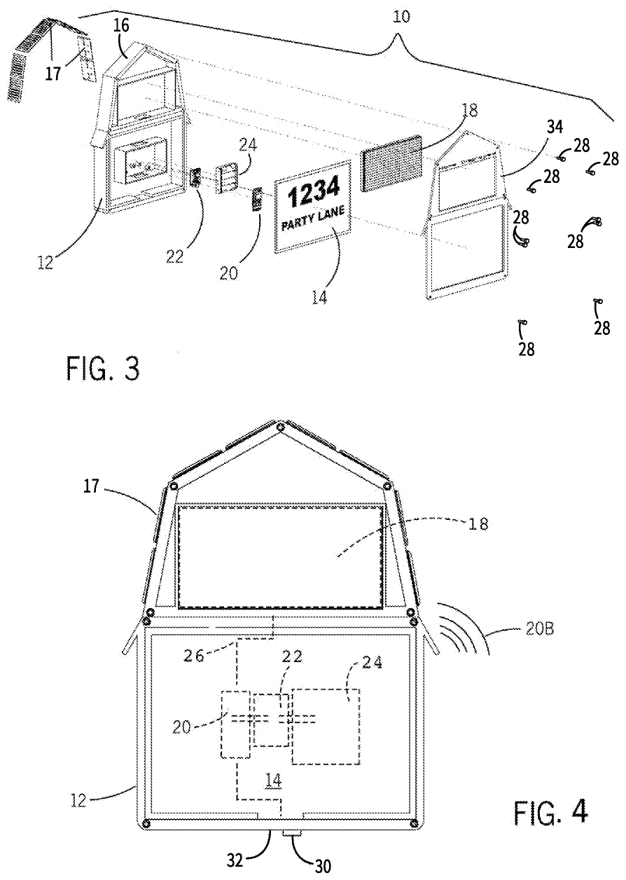

As shown in FIGS. 3 and 4, housing 12 houses a control module 20, a power source 24, a power source interface 22, and connection wires 26. In one or more embodiments, the housing 12 is closed off using a cover plate 34, which is secured to the housing 12 through a plurality of screws 28. In one or more embodiments, an outside surface of the housing 12 has a manual switch 30 for control the device 10. In one or more embodiments, device 10 can communicate with an outside computing device via Wi-Fi® or Bluetooth® 20B.

FIG. 3 shows an expanded view of device 10 and its internal components. In one or more embodiments, the internal components are in the center of device 10 where they will be protected from the weather and the environment by being placed behind the display screen 14. Specifically, the control module 20, power source 24, and power source interface 22 will be placed behind the display screen 14. In one or more embodiments, the internal components are secured within the housing 12 utilizing a combination of adhesive and pressure.

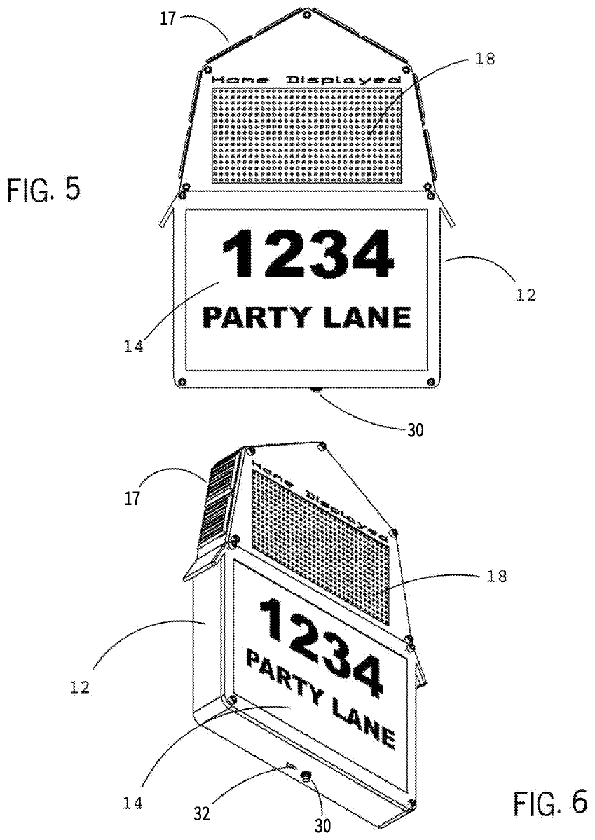

FIG. 4 is a front view outline of the device. In one or more embodiments, the control module 20 will be placed in a center containment box 19 within a lower portion of the housing 12. The containment box 19 will contain the other internal components as well, such as the power source 24 and the power source interface 22. FIG. 5 is a front view of one embodiment of device showing the location of the display screen 14 as well as the LED display 18 where you can see the main components and their positioning in the device. FIG. 6 shows a bottom perspective view showing the underside of device 10 with the button 30 and an external charging port 32. FIG. 6 also shows the partial mounting of the solar panel(s) 17 on the roofing structure 16 and both the display screen 14 and the LED display 18.

The present disclosure provides a graphically updateable and illuminated house address and/or message display device 10 to be placed by the front door of a house, apartment, or building. The display device 10 of the present disclosure is housed in a housing 12. The housing 12 may have a display screen 14 and a roof-like structure 16 with a peak on the top of the housing 12. The roof-life structure 16 may resemble the outline of the front of a house or barn. The housing 12 may comprise a void or a gap. The void or gap may be triangular or a multisided prism. The void may hold a light-emitting diode (LED) matrix 18. The LED matrix 18 may flash patterns or scroll text. In one or more embodiments, the LED matrix 18 may be on a face of the housing 12. In one or more embodiments, the LED matrix 18 may flash a red cross or scroll a message to emphasize the address for first responders to see. In one or more embodiments, the triangular void may also contain a speaker for playing sounds or music through the display device 10.

In one or more embodiments, the display screen 14 is an electronic screen (e-paper) that may display an address or message in various fonts, sizes, and colors. The display screen 14 may also display a message which may be read from a distance such as the distance from the house 11 to the street the house is located on, in daytime or nighttime. The display screen 14 may also display a graphic such as a numeral with or without a text, and with or without a background image or color.

In one or more embodiments, the display screen 14 may be updatable or changeable to suit the user's preferences. Display screen 14 uses little to no power once the graphic is displayed. The display screen 14 may communicate with a control module 20 and a power source 24. In one or more embodiments, control module 20 is a printed circuit board (PCB) microcontroller board with a connection wire 26 to attach to the display screen 14. In one or more embodiments, the power source 24 is a battery. In one or more embodiments, the battery 24 is connected by a connection wire 26 to a battery charge interface 22 and then to the PCB microcontroller 20 such that the battery will provide power to both the microcontroller 20 and the display screen 14 such as during a refresh. In one or more embodiments, the connection wires 26 are insulated copper wires or ribbon cables.

In one or more embodiments, the microcontroller board 20 is an ESP32 microcontroller. In one or more embodiments, the microcontroller board 20 has both Wi-Fi® and Bluetooth® connections on board and may connect to a phone or tablet using an app that will allow any image to be uploaded and refreshed to the display screen 14 and/or the L.E.D. matrix 18.

In one or more embodiments, the display screen 14 can handle a large temperate range, such as −15° F. to 140° F. and can hold an image for extended periods of time without any power going to the unit. In one or more embodiments, the battery 24 enables the microcontroller 20 to power up and then update the display screen 14 when instructed.

In one or more embodiments, to utilize the microcontroller 20 to control the display screen 14, the microcontroller 20 will first need to be connected to the display screen 14. Next, the battery charger interface 22 is connected to battery 24 and then to microcontroller 20.

In one or more embodiments, the housing 12 may have a hole with a button 30 that would allow for control of the device 20. In one or more embodiments, the button 30 could be programmed to activate a sequence for emergency use or to reset the device 10 to a new out of the box settings mode. In one or more embodiments, the housing 12 may also have a location on the bottom to have a charging port 32 visible to the user for the ability to connect an external battery to the device 10 to charge the power source 24.

In one or more embodiments, a mount or bracket may be needed to mount and hold the device 10 against a door or a wall of a house 11. In one or more embodiments, a lock or set screw may be utilized to prevent theft of the device 10. Alternatively, device 10 may have cutouts on the back of the device 10 to allow for hanging of the device 10 without a bracket. In such an embodiment, a plurality of screws could be screwed into a surface of a house 11 to hang device 10.

In one or more embodiments, device 10 may communicate with a computer or mobile app to initialize, set up, or control device 10. The app may guide a user and enable them to enter desired text or graphics for the display screen 14. Once the display screen 14 has been set, the microcontroller 20 may go into a sleep mode. This increases the stand-by time of device 10 and potentially enables a user to only recharge the device 10 once a year.

In one or more embodiments, control module 20 may include a digital greeting system. In one or more embodiments, the digital greeting system could utilize artificial intelligence or a large language model to identify the physical location of device 10, either by user input of GPS location tracking, and the system could respond to either motion or microphone input. In such an embodiment, device 10 would also include sensors such as PIR (Passive Infra-Red Sensor) motion detection, Radar/LIDAR object detection, a built-in microphone, and speaker. In such an embodiment, if an individual approached the building device 10 was secured to, the system would note the individual's presence and greet the individual with a “Hello, how can I help you today?” Depending on the response received, the greeting system would utilize artificial intelligence or a large language model to respond appropriately with a natural language response.

In one or more embodiments, housing 12 may be approximately two inches thick, enabling components to hide behind display screen 14. In one or more embodiments, one or more solar panel(s) 17 may be affixed to the roofing surfaces 16 that are at multiple angles to better catch the sunlight.

In one or more embodiments, the microcontroller 20 may change the display screen 14 based on user input or a clock. The display screen 14 may reset to a default home address image file after a certain period of time or at a specific time of day such as midnight. Certain conditions, such as sunrise, sunset, or other programmed conditions, may trigger set responses. In one or more embodiments, lighting may be enabled using motion detectors or other sensory input devices such as a photovoltaic light sensor.

In various embodiments disclosed herein, a single component can be replaced by multiple components and multiple components can be replaced by a single component to perform a given function or functions. Except where such substitution would not be operative, such substitution is within the intended scope of the embodiments.

The foregoing description of embodiments and examples has been presented for purposes of illustration and description. It is not intended to be exhaustive or limiting to the forms described. Numerous modifications are possible considering the above teachings. Some of those modifications have been discussed, and others will be understood by those skilled in the art. The embodiments were chosen and described in order to best illustrate principles of various embodiments as are suited to uses contemplated. The scope is, of course, not limited to the examples set forth herein, but can be employed in any number of applications and equivalent devices by those of ordinary skill in the art. Rather, it is hereby intended the scope of the disclosure to be defined by the claims appended hereto.

What is claimed is:

1. A digital sign comprising:
a housing unit;
a light-emitting diode display;
a display screen;
a control module;
a power source; and
a cover plate
wherein the light-emitting diode display and the display screen are visible from outside of the housing unit and wherein the control module and the power source are not visible from outside the housing unit.

2. The digital sign of claim 1, further comprising a power source interface; wherein the power source is connected to the power source interface, wherein the power source interface is connected to the control module, and wherein the control module is connected to the both the display screen and the light-emitting diode display through connection wires.

3. The digital sign of claim 2, further comprising a containment box located within the housing unit; wherein the control module, power source, and power source interface are contained within the containment box and wherein the containment box is covered by one or more of the light-emitting diode display and/or the display screen.

4. The digital sign of claim 2, further comprising a control switch accessible from outside of the housing unit and a charging port accessible from outside of the housing unit; wherein the control module is controllable by the control switch and wherein an external power source may be utilized by the charging port to provide excess power to the power source.

5. The digital sign of claim 1, further comprising a mount located on a rear surface of the housing unit wherein the digital sign may be mounted to a building by the mount.

6. The digital sign of claim 1, further comprising solar panels mounted on the housing unit, wherein the solar panels are connected to the power source to provide renewable power to the power source.

7. The digital sign of claim 1, wherein the control module contains a communication means such that the control module can be controlled through an external computing device.

8. The digital sign of claim 7, wherein the communication means is selected from the group consisting of Wi-Fi®, Bluetooth®, and combinations thereof.

9. The digital sign of claim 1, wherein the display screen is selected from the group consisting of an electronic paper display screen or an electronic ink display screen.

10. The digital sign of claim 1, wherein the display screen can operate in a temperature range of from about −15° F. to about 140° F.

11. The digital sign of claim 1, wherein the control module is a printed circuit board microcontroller.

12. The digital sign of claim 11, wherein the printed circuit board microcontroller is an ESP32 microcontroller.
